(19) United States
(12) Patent Application Publication
(10) Pub. No.: US 2026/0100236 A1
(43) Pub. Date: Apr. 9, 2026

(54) PATTERN-GENERATING DEVICE

(71) Applicant: ADVANTEST CORPORATION, Tokyo (JP)

(72) Inventors: Tokunori AKITA, Saitama (JP); Takeshi KAWAKAMI, Gunma (JP); Masaki FUJIWARA, Gunma (JP)

(21) Appl. No.: 19/415,709

(22) Filed: Dec. 10, 2025

Related U.S. Application Data
(63) Continuation of application No. PCT/JP2023/037487, filed on Oct. 17, 2023.

(51) Int. Cl. G11C 29/10; G11C 29/12

(52) U.S. Cl. CPC G11C 29/10; G11C 29/12015

(57) ABSTRACT

Provided is a pattern-generating device including: a timing-generating unit which generates a clock signal; a data-generating unit which generates multi-bit data used for generating a multi-level signal having three or more levels; and a control unit which controls the data-generating unit to generate the data, wherein the control unit outputs, based on the clock signal, a trigger signal which triggers the data-generating unit to generate the data, and the data-generating unit outputs, in response to the trigger signal, the multi-bit data for at least one of a rising edge or a falling edge of the clock signal.

The contents of the following patent application(s) are incorporated herein by reference:

NO. PCT/JP2023/037487 filed in WO on October 17, 2023.

### BACKGROUND

### 1. TECHNICAL FIELD

The present invention relates to a pattern-generating device.

### 2. RELATED ART

Patent document 1 describes "a testing device that determines whether a memory device 10 is acceptable or defective". RELATED ART DOCUMENTS Patent Documents Patent Document 1: Japanese Patent Application Publication No. 2004-30775 Patent Document 2: Japanese Patent Application Publication No. 2003-508758 Patent Document 3: Japanese Patent Application Publication No. H8-211126

### BRIEF DESCRIPTION OF THE DRAWINGS

FIG. 1 illustrates an example configuration of a testing device 100 along with a device under test 10.

FIG. 2 illustrates an example configuration of a pattern-generating device 20.

FIG. 3A illustrates an example of data DAT output by a data-generating unit 24.

FIG. 3B illustrates a variant of data DAT output by the data-generating unit 24.

FIG. 4 illustrates an example of data output by a calculation-data output unit 240.

FIG. 5A illustrates an example of data output by a consecutive-data output unit 244.

FIG. 5B illustrates an example of data output by a reduced-count-data output unit 246.

FIG. 6 illustrates a variant of data DAT output by the data-generating unit 24.

FIG. 7 illustrates an example of generation of a multi-level signal by a waveform-generating unit 30.

FIG. 8 illustrates an example of a computer 1000 by which a plurality of aspects of the present invention may be embodied in whole or in part.

### DESCRIPTION OF EXEMPLARY EMBODIMENTS

Hereinafter, the invention will be described through embodiments of the invention, but the following embodiments do not limit the invention as defined by the claims. In addition, not all of the combinations of features described in the embodiments are necessarily essential to the solution provided by the invention.

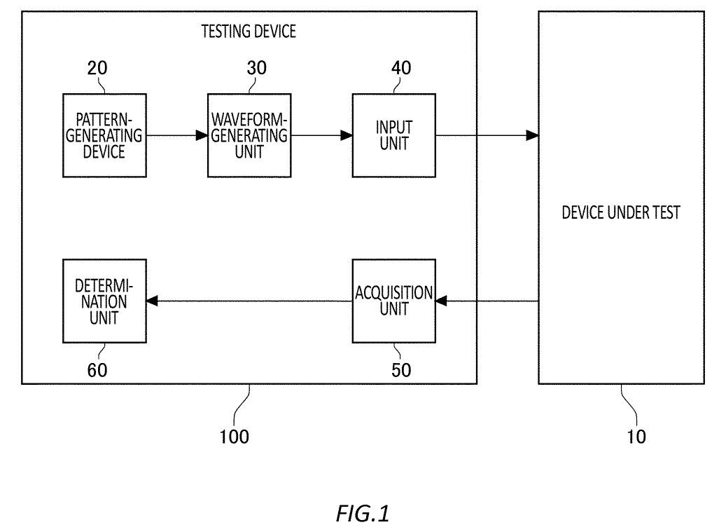

FIG. 1 illustrates an example configuration of a testing device 100 along with a device under test 10. The testing device 100 includes a pattern-generating device 20, a waveform-generating unit 30, an input unit 40, an acquisition unit 50, and a determination unit 60, and tests the device under test 10, e.g., an analog circuit, a digital circuit, a memory, or a system-on-chip (SOC). The testing device 100 inputs a test signal into the device under test 10, and determines, based on a response signal output by the device under test 10 in response to the test signal, whether the device under test 10 is acceptable or defective.

The test signal may be a multi-level signal having three or more levels. In this case, the device under test 10 may be a device capable of signal transmission in a Pulse Amplitude Modulation (PAM) scheme. As an example, the device under test 10 is a memory capable of signal transmission in the PAM4 scheme. In this case, the test signal is a multi-level signal having four levels.

The pattern-generating device 20 generates, via a data-generating unit 24 described below, multi-bit data DAT used for generating a multi-level signal having three or more levels. The multi-bit data may be data having a number of bits greater than one.

The waveform-generating unit 30 generates, by using multi-bit data DAT generated by the pattern-generating device 20, a multi-level signal DQ having three or more levels. As an example, the pattern-generating device 20 generates two-bit data DAT, and the waveform-generating unit 30 generates a multi-level signal DQ having four levels. Note that a number of levels of the multi-level signal DQ generated by the waveform-generating unit 30 is not limited thereto. The waveform-generating unit 30 may generate the multi-level signal DQ having three levels, and may generate the multi-level signal DQ having five or more levels.

The input unit 40 generates a test signal based on the multi-level signal DQ generated by the waveform-generating unit 30, and inputs the test signal into the device under test 10. The acquisition unit 50 acquires a response signal output by the device under test 10.

The determination unit 60 compares the response signal of the device under test 10 acquired by the acquisition unit 50 with a predetermined expected signal. The determination unit 60 determines, based on the comparison result of the response signal and the expected signal, whether the device under test 10 is acceptable or defective.

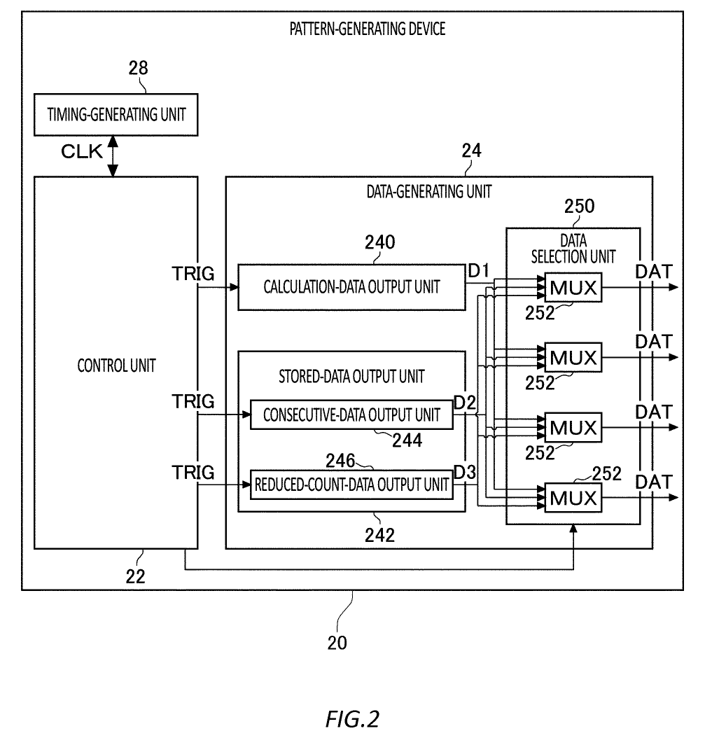

FIG. 2 illustrates an example configuration of the pattern-generating device 20. The pattern-generating device 20 includes a control unit 22, a data-generating unit 24, and a timing-generating unit 28.

The data-generating unit 24 generates multi-bit data DAT used for generating the multi-level signal DQ having three or more levels. The data-generating unit 24 may generate data DAT having a number of bits corresponding to the number of levels of the multi-level signal DQ. The data-generating unit 24 may generate multi-bit data DAT corresponding to the number of levels of the multi-level signal DQ generated by the waveform-generating unit 30. As an example, when the multi-level signal DQ has four levels, the data-generating unit 24 generates two-bit data DAT.

The control unit 22 controls the data-generating unit 24 to generate the data DAT. The timing-generating unit 28 generates a clock signal CLK. The control unit 22 outputs, based on the clock signal CLK, a trigger signal TRIG, which triggers the data-generating unit 24 to generate the data DAT.

The data-generating unit 24 may have a calculation-data output unit 240, a stored-data output unit 242, and a data selection unit 250.

The calculation-data output unit 240 may output, in response to the trigger signal TRIG, data by executing a calculation based on a calculation instruction by the control unit 22. The calculation-data output unit 240 of the present example outputs data D1. Details of the output of the data D1 and the calculation instruction by the calculation-data output unit 240 will be described below.

The stored-data output unit 242 may, in response to the trigger signal TRIG, output data that is stored. The stored-data output unit 242 may be a register to store data to be output, or may be a memory to store data to be output. Note that a configuration of the stored-data output unit 242 is not limited thereto. The stored-data output unit 242 may include a consecutive-data output unit 244 and a reduced-count-data output unit 246.

The consecutive-data output unit 244 may output, in response to the trigger signal TRIG, consecutive data. The consecutive-data output unit 244 of the present example outputs consecutive data D2. The consecutive-data output unit 244 may output the consecutive data D2 having a consecutive-data count of a predetermined number. For example, the consecutive-data output unit 244 outputs consecutive data D2 having a consecutive-data count of sixteen. Note that the consecutive-data count of the consecutive data D2 is not limited thereto. Details of the output of the consecutive data D2 by the consecutive-data output unit 244 will be described below.

The reduced-count-data output unit 246 may output, in response to the trigger signal TRIG, data having a smaller consecutive-data count than that of the consecutive data. The reduced-count-data output unit 246 of the present example outputs data D3. For example, when the consecutive-data count of the consecutive data D2 is sixteen, the reduced-count-data output unit 246 may output data D3 having a consecutive-data count of four. Note that the consecutive-data count of the data D3 is not limited thereto. Details of the output of the data D3 by the reduced-count-data output unit 246 will be described below.

Note that the consecutive-data output unit 244 and the reduced-count-data output unit 246 may be provided as independent different configurations or may be provided as an identical configuration. For example, operation of both the consecutive-data output unit 244 and the reduced-count-data output unit 246 may be achieved by letting the consecutive-data count of consecutive data D2 output by the consecutive-data output unit 244 or the consecutive-data count of data D3 output by the reduced-count-data output unit 246 variable.

The data selection unit 250 may select data to be output from the data output by the calculation-data output unit 240 and the stored-data output unit 242. The data selection unit 250 may select data to be output from the data output by the calculation-data output unit 240, the consecutive-data output unit 244, and the reduced-count-data output unit 246. The control unit 22 may control the data selection unit 250 to cause selection of data to be output.

The data selection unit 250 may include a plurality of multiplexers 252 which selects data to be output from the data output by the calculation-data output unit 240 and the stored-data output unit 242. The data selection unit 250 may include a plurality of multiplexers 252 for selects data to be output from the data output by the calculation-data output unit 240, the consecutive-data output unit 244 and the reduced-count-data output unit 246. The data selection unit 250 of the present example includes four multiplexers 252. A number of the multiplexers 252 included in the data selection unit 250 may be three or fewer, or may be five or more.

The data selection unit 250 may select data to be output by using a plurality of multiplexers 252, the number of which corresponds to the number of bits of the multi-bit data DAT. For example, when the number of bits of the multi-bit data DAT is two, the data selection unit 250 may select data to be output by using four multiplexers 252.

The number of the plurality of multiplexers 252 that the data selection unit 250 has and the number of the plurality of multiplexers 252 used by the data selection unit 250 for selects data to be output may be the same, or may be different. That is, the data selection unit 250 may have a plurality of multiplexers 252, the number of which is equal to or more than the number that corresponds to the number of bits of the multi-bit data DAT, and may select data to be output by using some or all of the plurality of multiplexers 252.

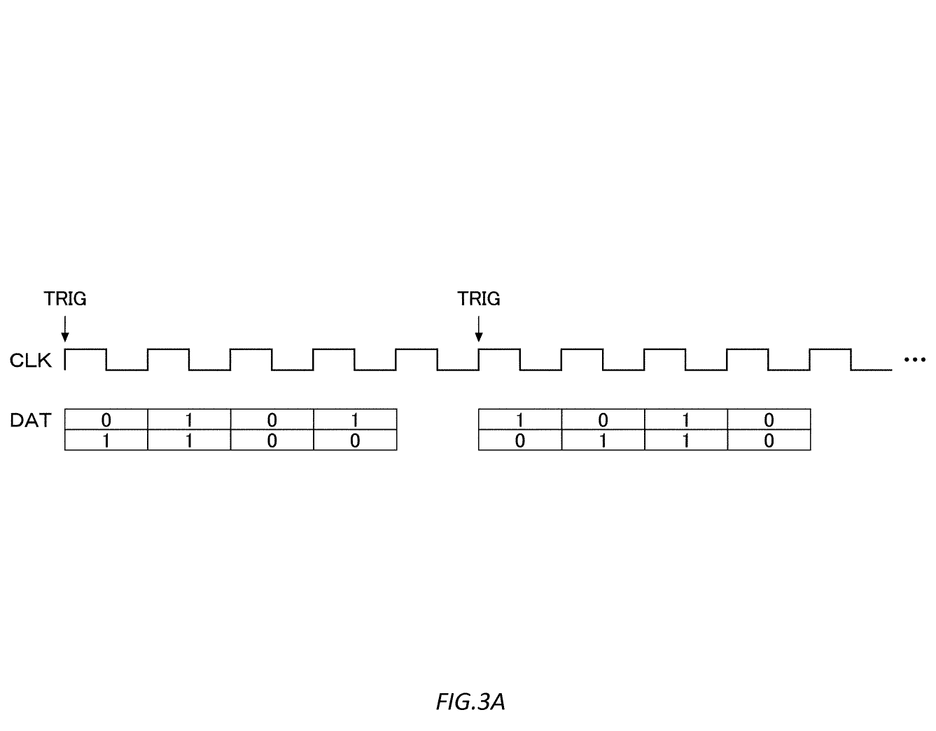

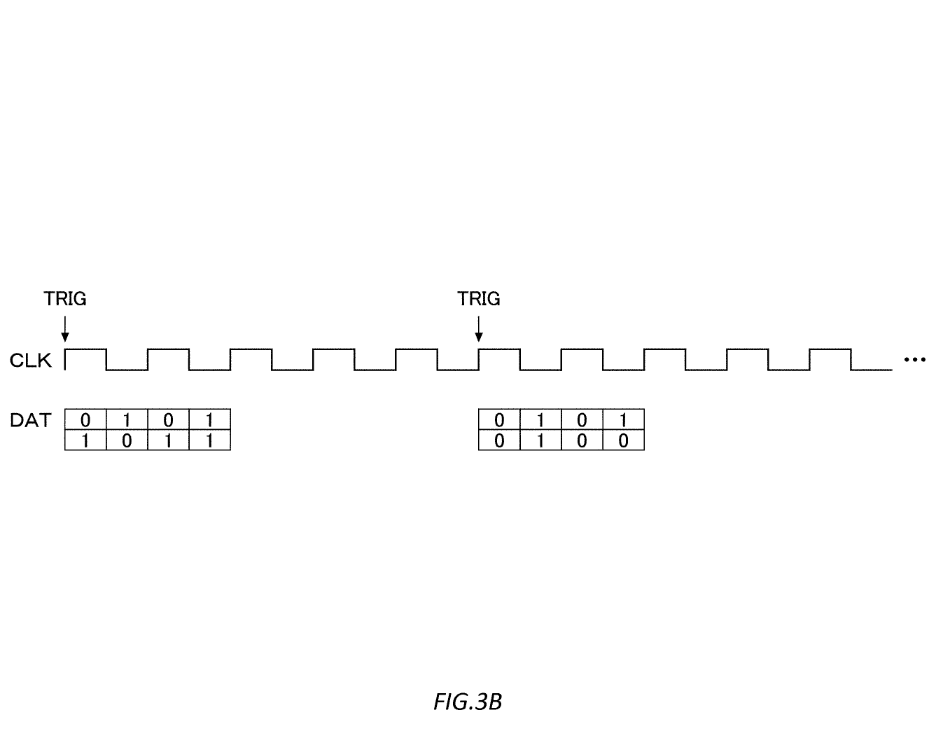

FIG. 3A illustrates an example of data DAT output by the data-generating unit 24. The data-generating unit 24 of the present example generates multi-bit data DAT for the Single Data Rate (SDR) scheme, wherein data transfer is performed at a rising edge of the clock signal CLK.

The data-generating unit 24 outputs, in response to the trigger signal TRIG, multi-bit data DAT for at least one of a rising edge or a falling edge of the clock signal CLK. The data-generating unit 24 of the present example outputs the multi-bit data DAT at the rising edge of the clock signal CLK.

When the multi-level signal DQ has four levels, the data-generating unit 24 may output, in response to the trigger signal TRIG, two-bit data DAT for at least one of the rising edge or the falling edge of the clock signal CLK. The data-generating unit 24 of the present example outputs two-bit data DAT at the rising edge of the clock signal CLK. As an example, the data-generating unit 24 outputs two-bit data DAT, which is represented by any one of "00", "01", "10", or "11".

The data-generating unit 24 may generate, in response to the trigger signal TRIG, data DAT that has a predetermined number of cycles. The data-generating unit 24 of the present example generates, in response to the trigger signal TRIG, multi-bit data DAT, which has four cycles. That is, the data-generating unit 24 of the present example generates multi-bit data DAT at rising edges of each of the four cycles. The data-generating unit 24 may generate multi-bit data DAT which has three or fewer cycles, and may generate multi-bit data DAT which has five or more cycles.

FIG. 3B illustrates a variant of data DAT output by the data-generating unit 24. The data-generating unit 24 of the present example is different from the example embodiment in FIG. 3A in that it generates multi-bit data DAT for the Double Data Rate (DDR) scheme, wherein data transfer is performed at the rising edge and the falling edge of the clock signal CLK.

The data-generating unit 24 outputs, in response to the trigger signal TRIG, multi-bit data DAT for at least one of the rising edge or the falling edge of the clock signal CLK. The data-generating unit 24 of the present example outputs the multi-bit data DAT at each of the rising edge and the falling edge of the clock signal CLK.

When the multi-level signal has four levels, the data-generating unit 24 may output, in response to the trigger signal TRIG, two-bit data at each of the rising edge and the falling edge of the clock signal CLK. As an example, the data-generating unit 24 outputs two-bit data DAT, which is represented by any one of "00", "01", "10", or "11".

The data-generating unit 24 may generate, in response to the trigger signal TRIG, data DAT that has a predetermined number of cycles. The data-generating unit 24 of the present example generates, in response to the trigger signal TRIG, multi-bit data DAT, which has two cycles. That is, the data-generating unit 24 of the present example generates the multi-bit data DAT at each of the rising edge and the falling edge of the two cycles. The data-generating unit 24 may generate multi-bit data DAT which has one cycle, and may generate multi-bit data DAT which has three or more cycles.

As described above, the data-generating unit 24 of the present example outputs multi-bit data DAT for at least one of the rising edge or the falling edge of the clock signal CLK. With this configuration, a device under test 10, which operates with signal transmission in a PAM scheme, can be tested at high speed. Note that the data-generating unit 24 may test the device under test 10, which operates with signal transmission in a Non Return to Zero (NRZ) scheme by outputting single-bit data DAT for at least one of the rising edge or the falling edge of the clock signal CLK. That is, the data-generating unit 24 of the present example can perform testing based on signal transmission in either an NRZ or PAM scheme by adjusting the number of bits of the data DAT to output.

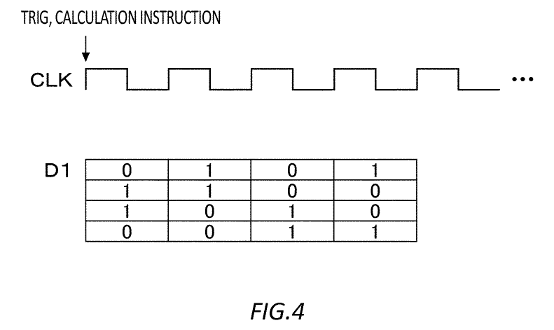

FIG. 4 illustrates an example of data output by the calculation-data output unit 240. The calculation-data output unit 240 may output, in response to the trigger signal TRIG, data by executing a calculation based on a calculation instruction by the control unit 22. The calculation instruction may include an instruction such as addition or subtraction on data D1. The calculation-data output unit 240 may execute a calculation on data D1 based on the calculation instruction, and update data D1 to output.

The calculation instruction may include a calculation algorithm. The calculation algorithm may be an algorithm for executing a predetermined series of calculations. The calculation-data output unit 240 may output algorithmic data in accordance with the calculation algorithm.

The calculation-data output unit 240 may output data D1 having a number of bits corresponding to the number of levels of the multi-level signal DQ, per cycle. The calculation-data output unit 240 of the present example outputs two-bit data per cycle. In this case, the multi-level signal DQ may have four levels.

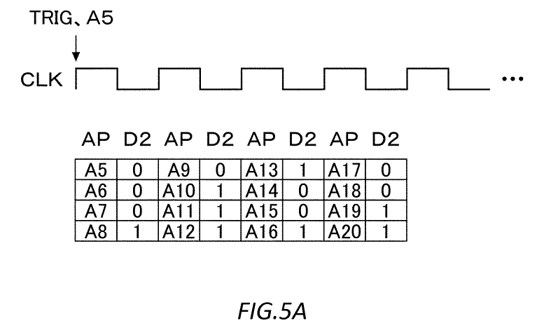

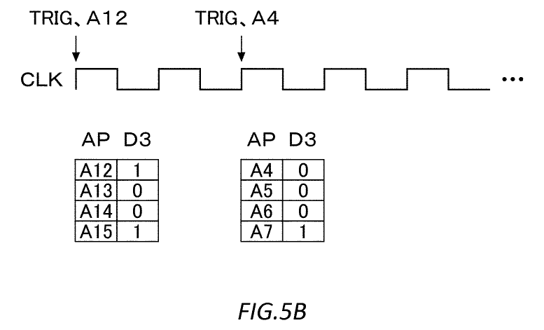

FIG. 5A illustrates an example of data output by the consecutive-data output unit 244. The consecutive-data output unit 244 may output, in response to the trigger signal TRIG, consecutive data. The consecutive-data output unit 244 may output consecutive data D2 having a predetermined consecutive-data count. The consecutive-data output unit 244 of the present example outputs consecutive data D2 in which the consecutive-data count is sixteen.

The consecutive-data output unit 244 may output data D2 having a number of bits corresponding to the number of levels of the multi-level signal DQ, per cycle. The consecutive-data output unit 244 of the present example outputs two-bit data per cycle. In this case, the multi-level signal DQ may have four levels.

The control unit 22 may designate a storage address AP to be a beginning address of data D2 output by the consecutive-data output unit 244. The control unit 22 may designate any beginning address. The control unit 22 of the present example designates address A5 as the beginning address. The consecutive-data output unit 244 may output consecutive data D2 having a predetermined consecutive-data count with the storage address AP designated by the control unit 22 as the beginning address. The consecutive-data output unit 244 of the present example outputs consecutive data D2, from address A5 designated by the control unit 22 as the beginning address, to address A20.

FIG. 5B illustrates an example of data output by the reduced-count-data output unit 246. The reduced-count-data output unit 246 may output, in response to the trigger signal TRIG, data having a smaller consecutive-data count than that of the consecutive data. The reduced-count-data output unit 246 of the present example outputs data D3 having a consecutive-data count of four, which is smaller than the consecutive-data count of the consecutive data D2, i.e., sixteen.

The reduced-count-data output unit 246 may output data having a number of bits corresponding to the number of levels of the multi-level signal DQ. That is, the consecutive-data count of the data D3 output by the reduced-count-data output unit 246 may be a number corresponding to the number of levels of the multi-level signal DQ. In the present example, the reduced-count-data output unit 246 outputs two-bit data. In this case, the multi-level signal DQ may have four levels.

The reduced-count-data output unit 246 may output data D3 having a number of bits corresponding to the number of levels of the multi-level signal DQ, per cycle. The reduced-count-data output unit 246 of the present example outputs two-bit data per cycle. In this case, the multi-level signal DQ may have four levels. That is, the consecutive-data count of the data D3 output by the reduced-count-data output unit 246 may match the number of data items output per cycle by the reduced-count-data output unit 246.

The control unit 22 may designate a storage address AP to be a beginning address of data D3 output by the reduced-count-data output unit 246. The control unit 22 may designate any beginning address. In the present example, the control unit 22 designates, as a beginning address, address A12 in the first cycle and address A4 in the third cycle. The reduced-count-data output unit 246 may output, with the storage address AP designated by the control unit 22 as the beginning address, data D3 having a smaller consecutive-data count than the consecutive data D2. The reduced-count-data output unit 246 of the present example outputs, in the first cycle, data D3, from address A12 designated by the control unit 22 as the beginning address, to address A15, and, in the third cycle, data D3, from address A4 designated by the control unit 22 as the beginning address, to address A7.

As described above, the data-generating unit 24 of the present example has a stored-data output unit 242 and can generate consecutive data starting from any beginning address. With this configuration, compared to a case where the data-generating unit 24 has only the calculation-data output unit 240, any data can be output without being constrained by a calculation algorithm. Since the data-generating unit 24 of the present example can output any data, degrees of freedom of testing the device under test 10 operating with signal transmission in a PAM scheme can be improved.

In addition, since the stored-data output unit 242 of the present example includes the consecutive-data output unit 244 and the reduced-count-data output unit 246, any data having different consecutive-data counts can be output. With this configuration, degrees of freedom of testing the device under test 10 operating with signal transmission in a PAM scheme can be improved.

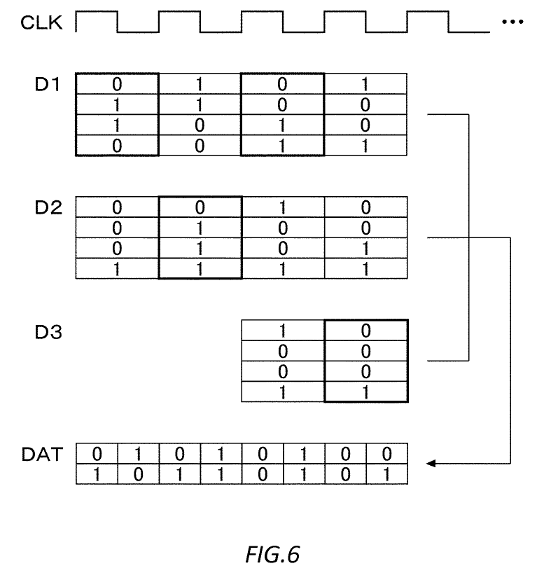

FIG. 6 illustrates a variant of data DAT output by the data-generating unit 24. In the present example, data D1 output by the calculation-data output unit 240, data D2 output by the consecutive-data output unit 244, data D3 output by the reduced-count-data output unit 246, and data DAT output by the data-generating unit 24 are shown along with the clock signal CLK. The data-generating unit 24 of the present example generates two-bit data DAT at each of the rising edge and the falling edge of the clock signal CLK. Note that, in the present example, the storage address AP is omitted.

The data selection unit 250 may select data to be output from the data output by the calculation-data output unit 240 and the stored-data output unit 242. The data selection unit 250 may select data to be output from the data output by the calculation-data output unit 240, the consecutive-data output unit 244, and the reduced-count-data output unit 246. The control unit 22 may control the data selection unit 250 to cause selection of data to be output.

In the present example, the data that is selected is indicated with a thick frame. The data selection unit 250 of the present example selects, as data DAT to output, data D1 output by the calculation-data output unit 240 in the first cycle and the third cycle, selects, as data DAT to output, data D2 output by the consecutive-data output unit 244 in the second cycle, and selects, as data DAT to output, data D3 output by the reduced-count-data output unit 246 in the fourth cycle. The data selection unit 250 may select data DAT to output by using a plurality of multiplexers 252.

The data-generating unit 24 outputs, at the rising edge of the first cycle, two-bit data “01” corresponding to a first half of data D1 selected by the data selection unit 250, and outputs, at the falling edge of the first cycle, two-bit data “10” corresponding to a second half of data D1 selected by the data selection unit 250. The data-generating unit 24 outputs, at the rising edge of the second cycle, two-bit data “01” corresponding to a first half of data D2 selected by the data selection unit 250, and outputs, at the falling edge of the second cycle, two-bit data “11” corresponding to a second half of data D2 selected by the data selection unit 250.

The data-generating unit 24 outputs, at the rising edge of the third cycle, two-bit data “00” corresponding to a first half of data D1 selected by the data selection unit 250, and outputs, at the falling edge of the third cycle, two-bit data “11” corresponding to a second half of data D1 selected by the data selection unit 250. The data-generating unit 24 outputs, at the rising edge of the fourth cycle, two-bit data “00” corresponding to a first half of data D3 selected by the data selection unit 250, and outputs, at the falling edge of the fourth cycle, two-bit data “01” corresponding to a second half of data D3 selected by the data selection unit 250.

As described above, the data-generating unit 24 of the present example outputs multi-bit data DAT for at least one of the rising edge or the falling edge of the clock signal CLK. With this configuration, a device under test 10, which operates with signal transmission in a PAM scheme, can be tested at high speed.

In the present example, the data selection unit 250 selects, for each cycle, any one of data D1 output by the calculation-data output unit 240, data D2 output by the consecutive-data output unit 244, or data D3 output by the reduced-count-data output unit 246, as data to be output. A method of selecting data by the data selection unit 250 is not limited thereto. The data selection unit 250 may select, for each cycle, a combination of data D1 output by the calculation-data output unit 240, data D2 output by the consecutive-data output unit 244, and data D3 output by the reduced-count-data output unit 246.

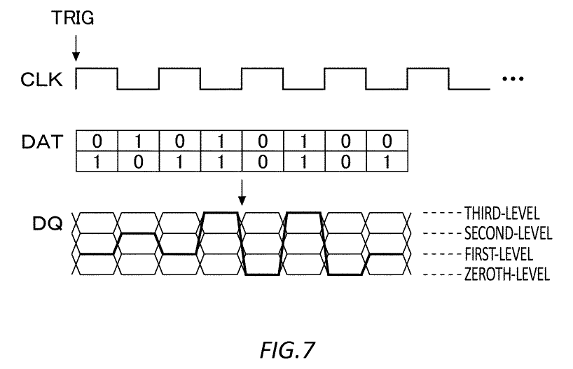

FIG. 7 illustrates an example of generation of a multi-level signal DQ by the waveform-generating unit 30. The waveform-generating unit 30 generates, by using multi-bit data DAT generated by the pattern-generating device 20, a multi-level signal DQ having three or more levels. In the present example, the waveform-generating unit 30 generates a multi-level signal DQ having four levels by using two-bit data DAT generated by the pattern-generating device 20. The waveform-generating unit 30 may generate a waveform of a level corresponding to the data generated by the pattern-generating device 20.

In the present example, the waveforms that are generated are indicated with a thick line. The waveform-generating unit 30 generates, at the rising edge of the first cycle, a first-level waveform corresponding to data “01” generated by the pattern-generating device 20, and generates, at the falling edge of the first cycle, a second-level waveform corresponding to data “10” generated by the pattern-generating device 20. The waveform-generating unit 30 generates, at the rising edge of the second cycle, a first-level waveform corresponding to data “01” generated by the pattern-generating device 20, and generates, at the falling edge of the second cycle, a third-level waveform corresponding to data “11” generated by the pattern-generating device 20.

The waveform-generating unit 30 generates, at the rising edge of the third cycle, a zeroth-level waveform corresponding to data “00” generated by the pattern-generating device 20, and generates, at the falling edge of the third cycle, a third-level waveform corresponding to data “11” generated by the pattern-generating device 20. The waveform-generating unit 30 generates, at the rising edge of the fourth cycle, a zeroth-level waveform corresponding to data “00” generated by the pattern-generating device 20, and generates, at the falling edge of the fourth cycle, a first-level waveform corresponding to data “01” generated by the pattern-generating device 20.

As described above, the pattern-generating device 20 of the present example outputs multi-bit data DAT for at least one of the rising edge or the falling edge of the clock signal CLK. With this configuration, the waveform-generating unit 30 can generate a multi-level signal DQ having three or more levels, and a device under test 10, which operates with signal transmission in a PAM scheme, can be tested at high speed.

Various embodiments of the present invention may be described with reference to flowcharts and block diagrams, wherein blocks may represent (1) steps of processes in which operations are executed or (2) sections of devices responsible for executing operations. Certain stages and sections may be implemented by a dedicated circuit, a programmable circuit supplied together with computer-readable instructions stored on computer-readable media, and/or processors supplied together with computer-readable instructions stored on computer-readable media. The dedicated circuit may include digital and/or analog hardware circuits, and may include integrated circuits (ICs) and/or discrete circuits. The programmable circuit may include a reconfigurable hardware circuit including logical AND, logical OR, logical XOR, logical NAND, logical NOR, and other logical operations, a memory element or the like, such as a flip-flop, a register, a field-programmable gate array (FPGA), and a programmable logic array (PLA), or the like.

A computer-readable medium may include any tangible device that can store instructions to be executed by a suitable device, and as a result, the computer-readable medium having instructions stored thereon includes a product including instructions that can be executed in order to create means for executing operations designated in the flowcharts or block diagrams. Examples of the computer-readable medium may include an electronic storage medium, a magnetic storage medium, an optical storage medium, an electromagnetic storage medium, a semiconductor storage medium, and the like. More specific examples of the computer-readable medium may include a floppy (registered trademark) disk, a diskette, a hard disk, a random access memory (RAM), a read-only memory (ROM), an erasable programmable read-only memory (EPROM or flash memory), an electrically erasable programmable read-only memory (EEPROM), a static random access memory (SRAM), a compact disc read-only memory (CD-ROM), a digital versatile disk (DVD), a Blu-ray (registered trademark) disk, a memory stick, an integrated circuit card, or the like.

The computer-readable instruction may include: an assembler instruction, an instruction-set-architecture (ISA) instruction; a machine instruction; a machine-dependent instruction; a microcode; a firmware instruction; state-setting data; or either a source code or an object code written in any combination of one or more programming languages, including an object oriented programming language such as Smalltalk (registered trademark), JAVA (registered trademark), C++, or the like, and a conventional procedural programming language such as a "C" programming language or a similar programming language.

The computer-readable instruction may be provided for a processor or programmable circuit of a programmable data processing device, such as a computer, locally or via a local area network (LAN), a wide area network (WAN) such as the Internet, or the like to execute the computer-readable instruction in order to create means for executing the operations specified in the flowcharts or block diagrams. Here, the computer may be a personal computer, or PC, a tablet computer, a smartphone, a workstation, a server computer, a general-purpose computer, a special-purpose computer, or the like, or may be a computer system to which a plurality of computers are connected. Such a computer system, to which the plurality of computers are connected, is also referred to as a distributed computing system, and is a computer in a broad sense. In a distributed computing system, a plurality of computers collectively execute a program by each of the plurality of computers executing a portion of the program, and passing data during the execution of the program among the computers as needed.

Examples of the processor include a computer processor, a central processing unit (CPU), a processing unit, a microprocessor, a digital signal processor, a controller, a microcontroller, and the like. The computer may include one processor or a plurality of processors. In a multiprocessor system including a plurality of processors, the plurality of processors collectively execute a program by each of the processors executing a portion of the program, and passing data during the execution of the program among the processors as needed. For example, in execution of multitasking, each of the plurality of processors may execute a portion of each task piece by piece by performing task-switching for each time slice. In this case, which portion of one program each processor is responsible for executing dynamically changes. Moreover, which portion of the program each of the plurality of processors is responsible for executing may be determined statically by multiprocessor-aware programming.

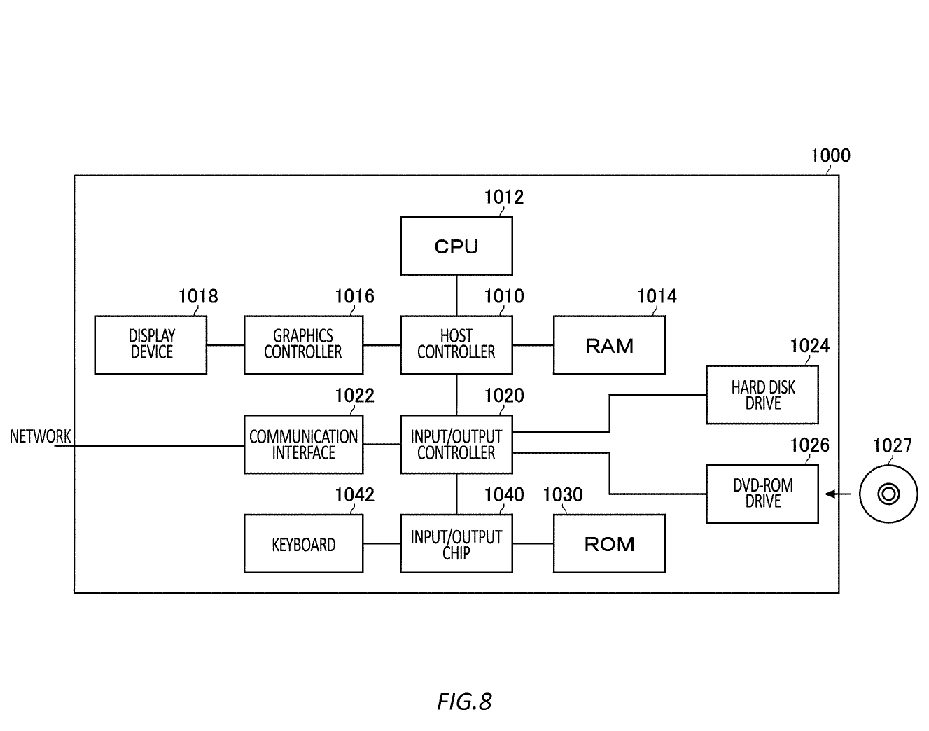

FIG. 8 illustrates an example of a computer 1000 by which a plurality of aspects of the present invention may be embodied in whole or in part. A program installed in the computer 1000 can cause the computer 1000 to function as an operation associated with the devices according to the embodiments of the present invention or as one or more sections of the devices, or can cause the operation or the one or more sections to be executed, and/or can cause the computer 1000 to execute a process according to the embodiments of the present invention or a step of the process. Such programs may be executed by a CPU 1012 to cause the computer 1000 to execute specific operations associated with some or all of the blocks in the flowcharts and block diagrams described in the present specification.

The computer 1000 according to the present embodiment includes the CPU 1012, a RAM 1014, a graphics controller 1016, and a display device 1018, which are interconnected by a host controller 1010. The computer 1000 also includes input/output units such as a communication interface 1022, a hard disk drive 1024, a DVD-ROM drive 1026, and an IC card drive, which are connected to the host controller 1010 via an input/output controller 1020. The computer also includes legacy input/output units such as a ROM 1030 and a keyboard 1042, which are connected to the input/output controller 1020 via an input/output chip 1040.

The CPU 1012 operates according to programs stored in the ROM 1030 and the RAM 1014, thereby controlling each unit. The graphics controller 1016 acquires image data generated by the CPU 1012 in a frame buffer or the like provided in the RAM 1014 or in itself, such that the image data is displayed on the display device 1018.

The communication interface 1022 communicates with another electronic device via a network. The hard disk drive 1024 stores programs and data used by the CPU 1012 in the computer 1000. The DVD-ROM drive 1026 reads a program or data from a DVD-ROM 1027 and provides the program or data to the hard disk drive 1024 via the RAM 1014. The IC card drive reads the programs and the data from the IC card, and/or writes the programs and the data to the IC card.

The ROM 1030 stores therein boot programs and the like executed by the computer 1000 at the time of activation, and/or programs that depend on the hardware of the computer 1000. The input/output chip 1040 may also connect various input/output units to the input/output controller 1020 via a parallel port, a serial port, a keyboard port, a mouse port, or the like.

Programs are provided by a computer-readable medium such as the DVD-ROM 1027 or the IC card. The programs are read from the computer-readable medium, are installed in the hard disk drive 1024, the RAM 1014, or the ROM 1030 which is also an example of the computer-readable medium, and are executed by the CPU 1012. Information processing written in these programs is read by the computer 1000, and provides cooperation between the programs and the various types of hardware resources described above. The device or method may be configured by implementing operations or processing of information according to use of the computer 1000.

For example, in a case where communication is performed between the computer 1000 and an external device, the CPU 1012 may execute a communication program loaded in the RAM 1014 and instruct the communication interface 1022 to perform communication processing based on a processing written in the communication program. Under the control of the CPU 1012, the communication interface 1022 reads transmission data stored in a transmission buffer processing area provided in a recording medium such as the RAM 1014, the hard disk drive 1024, the DVD-ROM 1027, or the IC card, transmits the read transmission data to the network, or writes reception data received from the network in a reception buffer processing area or the like provided on the recording medium.

In addition, the CPU 1012 may cause the RAM 1014 to read all or a necessary part of a file or database stored in an external recording medium such as the hard disk drive 1024, the DVD-ROM drive 1026 (DVD-ROM 1027), the IC card, or the like, and may execute various types of processing on data on the RAM 1014. Then, the CPU 1012 writes the processed data back into the external recording medium.

Various types of information, such as various types of programs, data, tables, and databases, may be stored in a recording medium and subjected to information processing. The CPU 1012 may execute, on the data read from the RAM 1014, various types of processing, including various types of operations, information processing, conditional judgement, conditional branching, unconditional branching, information search/replacement, or the like described throughout the present disclosure and specified by instruction sequences of the programs, and writes the results back to the RAM 1014. In addition, the CPU 1012 may search for information in a file, a database, or the like in the recording medium. For example, when a plurality of entries, each having an attribute value of a first attribute associated with an attribute value of a second attribute, is stored in the recording medium, the CPU 1012 may search, out of the plurality of entries, an entry with the attribute value of the first attribute specified that meets a condition, read the attribute value of the second attribute stored in said entry, and thereby acquire the attribute value of the second attribute associated with the first attribute meeting a predetermined condition.

The programs or software modules described above may be stored in a computer-readable medium on or near the computer 1000. In addition, a recording medium such as a hard disk or a RAM provided in a server system connected to a dedicated communication network or the Internet can be used as a computer-readable medium, thereby providing a program to the computer 1000 via the network.

While the present invention has been described by way of the embodiments, the technical scope of the present invention is not limited to the above-described embodiments. It is apparent to persons skilled in the art that various modifications or improvements can be made to the above-described embodiments. It is also apparent from the described scope of the claims that the embodiments which such modifications or improvements are made to can be included in the technical scope of the present invention.

Note that the operations, procedures, steps, stages, or the like of each process performed by a device, system, program, and method shown in the claims, embodiments, or diagrams can be performed in any order as long as the order is not specifically indicated by "prior to," "before," or the like and as long as the output from a previous process is not used in a later process. Even if the process flow is described using phrases such as "first" or "next" in the claims, embodiments, or diagrams, it does not necessarily mean that the process must be performed in this order.

### EXPLANATION OF REFERENCES

10: device under test, 20: pattern-generating device, 22: control unit, 24: data-generating unit, 28: timing-generating unit, 30: waveform-generating unit, 40: input unit, 50: acquisition unit, 60: determination unit, 100: testing device, 240: calculation-data output unit, 242: stored-data output unit, 244: consecutive-data output unit, 246: reduced-count-data output unit, 250: data selection unit, 252: multiplexer, 1000: computer, 1010: host controller, 1012: CPU, 1014: RAM, 1016: graphics controller, 1018: display device, 1020: input/output controller, 1022: communication interface, 1024: hard disk drive, 1026: DVD-ROM drive, 1027: DVD-ROM, 1030: ROM, 1040: input/output chip, 1042: keyboard.

WHAT IS CLAIMED IS:

1. A pattern-generating device comprising:
a timing-generating unit which generates a clock signal;
a data-generating unit which generates multi-bit data used for generating a multi-level signal having three or more levels; and
a control unit which controls the data-generating unit to generate the data, wherein
the control unit outputs, based on the clock signal, a trigger signal which triggers the data-generating unit to generate the data, and
the data-generating unit outputs, in response to the trigger signal, the multi-bit data for at least one of a rising edge or a falling edge of the clock signal.

2. The pattern-generating device according to claim 1, wherein
the data-generating unit includes a calculation-data output unit which outputs, in response to the trigger signal, data by executing a calculation based on a calculation instruction from the control unit.

3. The pattern-generating device according to claim 2, wherein
the calculation instruction includes a calculation algorithm, and
the calculation-data output unit outputs algorithmic data in accordance with the calculation algorithm.

4. The pattern-generating device according to claim 2, wherein
the data-generating unit includes a stored-data output unit which outputs, in response to the trigger signal, data which is stored.

5. The pattern-generating device according to claim 3, wherein
the data-generating unit includes a stored-data output unit which outputs, in response to the trigger signal, data which is stored.

6. The pattern-generating device according to claim 4, wherein
the stored-data output unit includes a consecutive-data output unit which outputs, in response to the trigger signal, consecutive data.

7. The pattern-generating device according to claim 6, wherein
the stored-data output unit includes a reduced-count-data output unit which outputs, in response to the trigger signal, data having a smaller consecutive-data count than that of the consecutive data.

8. The pattern-generating device according to claim 7, wherein
the reduced-count-data output unit outputs data having a number of bits corresponding to a number of levels of the multi-level signal.

9. The pattern-generating device according to claim 7, wherein
the multi-level signal has four levels, and
the reduced-count-data output unit outputs two-bit data per cycle of the clock signal.

10. The pattern-generating device according to claim 4, wherein
the data-generating unit includes a data selection unit which selects data to be output from the data output by the calculation-data output unit and the stored-data output unit.

11. The pattern-generating device according to claim 6, wherein
the data-generating unit includes a data selection unit which selects data to be output from the data output by the calculation-data output unit and the stored-data output unit.

12. The pattern-generating device according to claim 10, wherein
the data selection unit includes a plurality of multiplexers for selects data to be output from the data output by the calculation-data output unit and the stored-data output unit.

13. The pattern-generating device according to claim 12, wherein
the data selection unit selects data to be output by using the plurality of multiplexers, a number of which corresponds to a number of bits of the multi-bit data.

14. The pattern-generating device according to claim 1, wherein
the multi-level signal has four levels, and
the data-generating unit outputs, in response to the trigger signal, two-bit data for at least one of a rising edge or a falling edge of the clock signal.

15. The pattern-generating device according to claim 2, wherein
the multi-level signal has four levels, and
the data-generating unit outputs, in response to the trigger signal, two-bit data for at least one of a rising edge or a falling edge of the clock signal.

16. The pattern-generating device according to claim 1, wherein
the multi-level signal has four levels, and
the data-generating unit outputs, in response to the trigger signal, two-bit data at each of a rising edge and a falling edge of the clock signal.

17. The pattern-generating device according to claim 2, wherein
the multi-level signal has four levels, and
the data-generating unit outputs, in response to the trigger signal, two-bit data at each of a rising edge and a falling edge of the clock signal.

18. A testing device comprising the pattern-generating device according to claim 1.

19. A pattern-generating method comprising:
generating, by a computer, a clock signal;
generating, by the computer, multi-bit data used for generating a multi-level signal having three or more levels; and
controlling, by the computer, to generate the data, wherein
the controlling to generate the data includes outputting, based on the clock signal, a trigger signal which triggers to generate the data, and
the generating of the data includes outputting, in response to the trigger signal, the multi-bit data for at least one of a rising edge or a falling edge of the clock signal.

20. A non-transitory computer-readable medium having recorded thereon a program which, executed by a computer, causes the computer to function as:
a timing-generating unit which generates a clock signal;
a data-generating unit which generates multi-bit data used for generating a multi-level signal having three or more levels; and
a control unit which controls the data-generating unit to generate the data, wherein
the control unit outputs, based on the clock signal, a trigger signal which triggers the data-generating unit to generate the data, and
the data-generating unit outputs, in response to the trigger signal, the multi-bit data for at least one of a rising edge or a falling edge of the clock signal.
